(19) United States
(12) Patent Application Publication
(10) Pub. No.: US 2022/0201893 A1
(43) Pub. Date: Jun. 23, 2022

(54) HEAT EXCHANGER, IN PARTICULAR FOR POWER ELECTRONICS

(71) Applicant: AVL Software and Functions GmbH, Regensburg (DE)

(72) Inventors: Christoph Bauer, Regensburg (DE); Christian Heuer, Leuna OT Kötzschau (DE); Katharina Berberich, Regensburg (DE); Peter Weiss, Regensburg (DE)

(21) Appl. No.: 17/554,834

(22) Filed: Dec. 17, 2021

(30) Foreign Application Priority Data
Dec. 17, 2020 (DE) 10 2020 133 973.9

(51) Int. Cl. H05K 7/20

(52) U.S. Cl. CPC H05K 7/2039; F28F 21/06; H05K 7/20927

(57) ABSTRACT

Heat exchanger, in particular for cooling power electronics, comprising an insulating element which separates a first fluid medium, which is in contact with a heat source, from a second fluid medium, which differs in at least one property from the first fluid medium and which is in fluid connection with a heat sink or is itself a heat sink, and a heat transfer element which has a higher thermal conductivity than the insulating element, wherein the insulating element comprises at least a first passage opening in which a first heat transfer element is arranged, wherein the heat transfer element is thermally connected both to the first fluid medium and/or the heat source, and to the second fluid medium and is fluidically sealed with respect to the insulating element by means of a sealing element.

### PRIORITY CLAIM

This application claims the benefit of priority from Germany Patent Application No. 10 2020 133 973.9, filed Dec. 17, 2020, the contents of which are incorporated by reference in its entirety.

### FIELD OF THE INVENTION

The invention relates to a heat exchanger, in particular for power electronics for cooling the power electronics, wherein the power electronics comprise at least one power module and at least one ancillary component. The heat exchanger comprises an insulating element separating a first fluid medium, which is in contact with a heat source, from a second fluid medium, which differs in at least one property from the first fluid medium and which is in fluid connection with a heat sink or is itself a heat sink.

### BACKGROUND OF THE INVENTION

It is known from the prior art that heat exchangers of power electronics can be made of thermally conductive materials such as aluminum. This offers the advantage of being able to cool all main components directly via the heat exchanger from a thermal point of view. Furthermore, ancillary components, which have a much lower power loss, can also be cooled directly or indirectly via this heat exchanger. The thermal connection is made by introducing the heat flow either directly into the heat exchanger or indirectly into the heat exchanger via other conductive materials.

New are heat exchangers made of plastic for cooling power electronics. The main components are usually directly exposed to the cooling medium, as the heat conduction through the plastic heat exchanger mostly does not have the desired quality. However, this only ensures that the main components are cooled. The ancillary components, however, cannot be connected to the heat exchangers as described above, since the desired or even (in particular for their safe and permanent operation) necessary quality of thermal resistance is not achieved via the thermally only slightly conductive plastic.

Accordingly, it is the object of the present invention to overcome the disadvantages of the prior art.

### SUMMARY OF THE INVENTION

This task is solved by a heat exchanger with the features of patent claim 1.

The key idea of the invention is to provide a heat exchanger comprising
an insulating element, wherein the insulating element separates a first fluid medium, which is in contact with a first heat source, from a second fluid medium, which differs in at least one property from the first fluid medium and which is in fluid connection and/or contact with a heat sink or is itself a heat sink, and
a first heat transfer element having a higher thermal conductivity than the insulating element.

According to the invention, the insulating element has a first passage opening in which the first heat transfer element is arranged, wherein the first heat transfer element is thermally connected both to the first fluid medium and/or the heat source, and to the second fluid medium and, together with a sealing element, fluidically seals the passage opening. Such a heat exchanger makes it very easy to conduct a fluid medium to the vicinity of a heat source, wherein it is thermally shielded from the environment during transport by the insulating element.

In the area of the heat source, the insulating element is interrupted at least sectionally. However, fluid leakage or mixing of the first fluid medium and the second fluid medium through this disconnection/(passage) opening is prevented by the fact that a heat transfer element is inserted into this opening and the opening, together with a sealing element fluidically seals the passage opening. The heat transfer element has a higher thermal conductivity than the insulating element, so that a heat transfer from the heat source to the second fluid medium can take place through the heat transfer element and thus also through the disconnection in the insulating element.

Preferably, the first heat transfer element is made of a material with very good thermal conductivity. Preferably, this material has a thermal conductivity X, of >150 W/(m·K), preferably >160 W/(m·K), preferably >170 W/(m·K), preferably >200 W/(m·K), further preferably >300 W/(m·K) and in particular preferably >400 W/(m·K). Materials selected from a group comprising copper, gold, silver, brass, tungsten, iron, aluminum, magnesium, silicon and alloys with at least one of these metals have been shown to be particularly suitable for forming a first heat transfer element.

Preferably, the first heat transfer element is in thermal connection with the second fluid medium by means of a pin heat sink. This allows the surface area available for heat transfer between the first heat transfer element and the second fluid medium to be increased and the energy transfer can therefore take place particularly efficiently. Alternatively or cumulatively with regard to the pin heat sink, it is conceivable to provide an arrangement which, like the pin heat sink, increases a surface which is in contact with the second fluid medium, so that an improved heat transfer is possible. The arrangement or the pin heat sink, respectively, are arranged at the heat transfer element or are an integral part of the heat transfer element.

Preferably, the first heat transfer element is designed as a screw element. This allows it to be easily screwed into the first passage opening. For this purpose, the first passage opening is designed in such a way that the screw element can be screwed in. Of course, further designs for the heat transfer element are conceivable. In particular, a friction locking between the heat transfer element and the passage opening could also be conceivable, for example an interference fit. In particular, the above-mentioned selection of suitable materials allows sufficient stiffness and/or a sufficiently large torsional moment of inertia to screw such a screw element into an opening in the insulating element. If greater stiffness and/or a greater torsional moment of inertia is desired or necessary, a deviation from the above materials and the selection of stronger materials is also conceivable and advantageous.

Preferably, the screw element has a screw head with a geometry selected from a group comprising external hexagon, external square, internal hexagon, hexalobular internal, slot and cross slot, and which is preferably suitable for form-fitting with a tool. Such a geometry makes it particularly easy to screw a heat transfer element formed as a screw element into the insulating element. In particular, it is preferred that the screw-in can be carried out with conventional tools which can be applied to the screw head in a form-fitting manner.

In particular, when the heat transfer element is designed as a screw element, it is preferred that the screw element has a geometry at the end opposite the end having the screw head, which enables it to be screwed into the insulating element without having to create an opening beforehand (for example by means of a further tool). Depending on the material of the insulating element, this can be achieved, for example, by the screw element having a thread whose slope is adapted to the material of the insulating element.

Preferably, the heat transfer element has, at least in sections, a geometry that forms a form fit with the passage opening in the insulating element. In particular, it is preferred that this form fit prevents the first and/or second fluid medium from passing through the opening in the insulating element. This can be achieved, for example, by suitable geometry and material selection. It is conceivable, for example, that a thread of a heat transfer element in the form of a screw element effects the form fit and thus has a sealing effect. In addition or as an alternative, a screw head could also produce the form fit with a surface of the insulating element in such a way that it rests on the surface in a sealing manner or penetrates the surface in sections in a form-fitting manner. If necessary, the leak tightness could be supported by an additional sealant.

Preferably, the heat exchanger has a sealing element that prevents the first and/or second fluid medium from passing through an opening in the insulating element. Preferably, the sealing element seals the opening with a form fit at least sectionally. In particular, it is preferred that the sealing element together with the heat transfer element seal the opening in the insulating part (for the first and/or second fluid). The sealing element is particularly preferably an O-ring.

A heat exchanger as described above offers in particular the advantage that it can be used extremely easily also for heat dissipation from several heat sources. Prior adaptation of the heat exchanger is generally not necessary for this purpose, since the openings in the insulating element can be made at the point where the insulating element comes closest to the respective heat source. After inserting a heat transfer element into such an opening, a heat source is thermally connected to the second fluid medium so that the second fluid medium can dissipate heat.

This means that a heat exchanger can be manufactured particularly easily and in large quantities without having to adapt its geometry to the subsequent arrangement in a system to be cooled. Instead, it is possible to manufacture the main components of the heat exchanger independently of the installation arrangement and only at the installation site to insert the openings in the insulating element at those points where heat dissipation is required.

In a preferred embodiment, the first heat source is a power module. A heat exchanger as described above has been shown to be particularly suitable for cooling electronic components. If necessary, in a preferred embodiment the heat transfer element can be thermally connected to the power module by means of the first fluid medium or a further third heat transfer element. If the power module is at least partially enclosed by the first fluid medium (for example, air, inert gas or cooling water) and preferably at least partially flowed around in such a way that it ensures sufficient heat transfer to the heat transfer element, an additional heat transfer element is not absolutely necessary. If sufficient heat transfer to the heat transfer element cannot be ensured, this is ensured by a third heat transfer element in an advantageous embodiment. The third heat transfer element is preferably selected from a group comprising a thermal paste, a gap pad, an adhesive and a metal and any combination thereof.

In conjunction with the cooling of power electronics, the first heat transfer element is also referred below to as a “cooling connection element”. The term “cooling connection element” is to be understood as synonymous with “heat transfer element”.

In a preferred embodiment, at least one second heat transfer element is provided, which is arranged in a second passage opening of the insulating element. In this case, the second heat transfer element is preferably thermally connected both to the first fluid medium and/or a further heat source and to the second fluid medium and, together with a sealing element, fluidically seals the passage opening. Such a design of the heat exchanger allows a particularly efficient removal of heat from several heat sources. The design with several heat transfer elements arranged in different passage openings of the insulating element is particularly advantageous if the heat sources are arranged at a distance from one another. This can also be used advantageously to allow heat sources that have not undergone cooling, as in the prior art, to also be coolable.

Particularly preferably, the second fluid medium is part of a cooling circuit. In particular, the cooling circuit can be an existing cooling circuit of a system. Even if only a first heat transfer element is provided to dissipate the heat of a first heat source, the heat can be efficiently dissipated by a cooling circuit containing the second fluid medium. However, this embodiment is particularly advantageous if the heat of multiple heat sources is to be dissipated. These additional heat source(s) can be thermally connected to the second fluid medium by means of one or more second heat transfer element(s). In the cooling circuit design, the heat to be dissipated from all heat sources thermally connected to this cooling circuit by means of a heat transfer element can be dissipated together.

Preferably, the second heat transfer element is thermally connected to the further heat source by means of the first fluid medium or a further third heat transfer element. Independently of the third heat transfer element for connecting the first heat transfer element, the further third heat transfer element for connecting the second heat transfer element to the further heat source is preferably selected from a group comprising a thermal paste, a gap pad, an adhesive and metals and any combination thereof. The further heat source is preferably an ancillary component.

Preferably, at least one of the at least one ancillary component is selected from a group comprising a DC link, a bus bar and a switch element. This list is not intended to be exhaustive, so that further or other ancillary components are conceivable depending on the area of application.

Preferably, the insulating element comprises a plastic. It is further preferred that the insulating element consists at least partially of a plastic and preferably predominantly of a plastic. In particular, it is preferred that the insulating element is made of a plastic. This allows an insulating element to be adapted to a given geometry in a particularly flexible manner. It would also be conceivable not to keep the geometry of the insulating element rigid, but to make the insulating element flexible, at least sectionally. In the case of a flexible design, for example as a flexible hose, the hose could be specifically arranged in such a way that it is guided sectionally in the vicinity of a heat source. An opening suitable for accommodating a heat transfer element can be inserted in a section of great proximity to a heat source.

A preferred embodiment of the heat exchanger is set forth below by way of example. However, the embodiments described for this example are also intended to be considered generally disclosed for any heat exchanger as described above in its most general form.

According to one embodiment, the exemplary heat exchanger is used to cool power electronics. In this example, the power electronics comprise a power module and at least one ancillary component. The heat exchanger has a cooling circuit with a fluid cooling medium, through which the power module and the at least one ancillary component are cooled directly or indirectly. The heat exchanger comprises an insulating element formed of a plastic material and having a first passage opening into which a first cooling connection element is inserted. The first cooling connection element is in thermal connection on the one hand with the cooling circuit and the cooling medium conducted therein and on the other hand with the power module in order to cool the power module. A further cooling connection element is also in thermal connection on the one hand with the cooling medium guided in the cooling circuit and on the other hand with a first ancillary component in order to cool the first ancillary component.

By a power module is meant a switching element as in the usual sense, for example the power module comprises an IGBT power semiconductor, wherein other known embodiments are also conceivable.

By an ancillary component it is to be understood that this is a component of the power electronics which does not correspond to the power module. According to a particularly preferred embodiment, the ancillary component may be at least one selected from a group comprising a DC link capacitor, a busbar, a switch element, an active EMC filter and/or a single filter component, a passive EMC filter and/or a single filter component, a power or control board and/or a single board component, a capacitor discharge means, a capacitor and a transformer.

Due to the great flexibility of the heat exchanger described above, its application for heat dissipation in almost any adiabatic installation space is conceivable and possible.

Preferably, the cooling circuit comprising the cooling medium is designed and intended to cool both the power module and at least one ancillary component to be cooled. Further cooling circuits or cooling devices for cooling the ancillary components are therefore not necessary, so that the overall space requirement as well as the material input can be reduced. The fact that the heat exchanger is at least partially, preferably completely, made of a plastic material means that the weight can be significantly reduced. The heat exchanger has a corresponding design which defines the cooling circuit in which the cooling medium is arranged and moves. By definition, the heat exchanger comprises the cooling circuit, the cooling medium and the further components as described according to the invention. The definition of the cooling circuit can be, for example, a housing, wherein the housing is formed at least partially consisting of the plastic material.

Preferably, the components of the power electronics are cooled by a single cooling circuit as described above, wherein preferably only the components to be cooled are connected to the cooling circuit. However, if the available installation space allows further cooling circuits or if individual components require individual (additional) cooling, at least one further cooling circuit could also be provided. Preferably, but not necessarily, this is also a cooling circuit of the type described above.

The components to be cooled, in particular the ancillary components, are each connected or in active contact with the cooling circuit or the cooling medium in accordance with the invention.

According to a preferred embodiment, the plastic is a plastic that is suitable for the application of the heat exchanger, i.e. the plastic should be heat resistant and resistant to the cooling medium. It should also have a certain inherent rigidity, so that no bending or other bending is permitted during use of the heat exchanger, or only to a limited extent. Plastics containing polyamides or at least consisting essentially of polyamide have proved to be particularly suitable. Preferred polyamide is PA66. In a preferred embodiment, this is reinforced and/or heat stabilized.

In order to be able to provide a good thermal connection of the ancillary component to the cooling circuit and the cooling medium by means of the cooling connection element, it is provided according to a particularly preferred embodiment that the cooling connection element is made of a material with good thermal conductivity, wherein the cooling connection element preferably consists of copper, gold, silver, brass, tungsten, iron and/or aluminum. A selection is made depending on the requirement or cost framework.

In order to provide an even better thermal connection of the ancillary component to the cooling circuit and the cooling medium by means of the cooling connection element, it is provided according to a preferred embodiment that the first cooling connection element is in thermal connection with the cooling circuit and the cooling medium by means of a pin heat sink. The pin heat sink is also known as a so-called pin fin structure, wherein other structures are also conceivable by which the surface of the cooling connection element in contact with the cooling medium is increased. The pin fin structure, but also other structures, not only work particularly well due to the large contact surface, but also influence the flow of the cooling medium in such a way that a better heat transfer coefficient is achieved. This, together with the larger surface area available for energy transfer, is advantageous for heat dissipation.

According to a particularly preferred embodiment, the first cooling connection element fluidically seals the first passage opening so that no cooling medium can escape from the cooling circuit through the first passage opening in order to maximize the efficiency of the heat exchanger, wherein the first cooling connection element preferably comprises a sealing element.

According to a preferred embodiment, the sealing element is an O-ring. However, for some applications, other sealing elements have been shown to be suitable and advantageous. Preferably, the sealing element is selected from a group including an O-ring, a tapered sealing thread, a flat gasket, a thread sealant, and a sealing tape. It has also been found that fasteners other than threads are advantageous for some applications. Therefore, in an alternative embodiment thereto, a fastener for securing the cooling connection element is selected from a group including a crimp, a clamp, a clip, and a bayonet fastener.

For further optimization of the thermal connection, it is provided according to a preferred embodiment that a third heat transfer element is arranged between the first cooling connection element and the first ancillary component, which is preferably designed as a first heat conducting layer.

The third heat transfer element, or the heat conducting layer, can be designed in a variety of ways, for example as a heat conducting paste, a gap pad, an adhesive or the like, depending on the area of application and the boundary conditions. It is particularly advantageous if the heat conducting layer is electrically insulating. Of course, it is particularly advantageous if the heat conducting layer is designed to be thermally highly conductive. It is further advantageous if the heat conducting layer is designed to compensate for unevenness. For example, the heat conducting layer can be flexible or elastically or plastically deformable and thus also serve as tolerance compensation.

According to a further preferred embodiment, it may be provided that the first cooling connection element is formed as a screw element and is screwed into the first passage opening.

According to a further preferred embodiment, it is provided that at least one further cooling connection element is provided, which is introduced in a corresponding at least one further passage opening of the heat exchanger and is in thermal connection on the one hand with the cooling circuit and the cooling medium and on the other hand with the first ancillary component.

It is thus conceivable that a second, a third, . . . , n-th cooling connection element is provided, which is inserted in a corresponding second, third, . . . , n-th passage opening of the heat exchanger. These are in thermal connection with the first ancillary component, analogously to the first connection element, so that overall the cooling capacity for the first ancillary component can be increased. This can also apply to any further ancillary component to be cooled.

It is also conceivable that at least one further cooling connection element is provided, which is introduced into a corresponding at least one further passage opening of the heat exchanger and is in thermal connection on the one hand with the cooling circuit and the cooling medium and on the other hand with at least one further ancillary component.

This means that a second, a third, . . . , n-th cooling connection element is provided, which is inserted in a corresponding second, third, . . . , n-th passage opening of the heat exchanger. These are in thermal connection with the respective second, third, . . . , n-th ancillary component, analogous to the first connection element, so that the overall cooling capacity can be increased.

Further advantageous embodiments result from the dependent claims.

### BRIEF DESCRIPTION OF THE DRAWINGS

Preferred and alternative examples of the present invention are described in detail below with reference to the following drawings. Furthermore, further objectives, advantages and purposes of the present invention are to be taken from the following description in connection with the drawings. In the drawings:

FIG. 1 shows a section of a heat exchanger according to a preferred embodiment.

### DETAILED DESCRIPTION OF THE PREFERRED EMBODIMENT

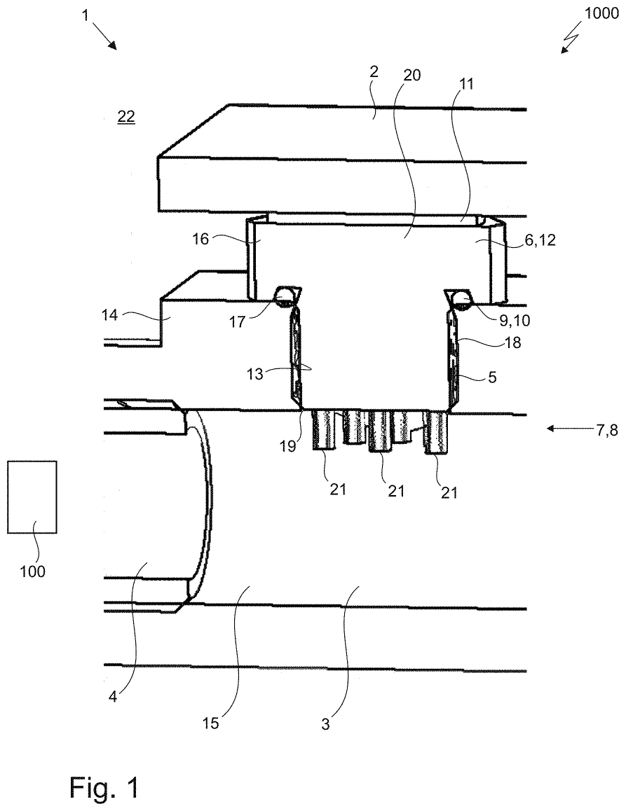

FIG. 1 shows a section of a heat exchanger 1, wherein the section shown serves to cool a heat source 2, in this case a first ancillary component 2. The ancillary component 2 is shown in stylized form. Analogously, the heat exchanger can also be used for cooling any heat source, for example a first heat source, in particular a power module of a power electronics.

In the exemplary section shown, it is shown that the heat exchanger 1 is provided for power electronics 1000 for cooling the power electronics 1000, wherein the power electronics 1000 comprises at least one power module 100 and at least one ancillary component 2. The ancillary component 2 is surrounded, at least sectionally, by a first fluid medium 22. This could be, for example, air or an inert gas. Typically, however, the heat that can be dissipated by this medium is limited, so that additional devices are required to be able to ensure efficient heat dissipation.

In the example shown, this is realized by the heat exchanger 1, which comprises a cooling circuit 3 with a second fluid medium 4, which is also referred to as cooling medium 4. The second fluid medium 4 is preferably pumped around within the cooling circuit, wherein it can release heat (for example to the ambient air) at at least one area. The at least one power module 100 (shown only schematically) and the at least one ancillary component 2 can be cooled directly or indirectly by means of the cooling circuit 3. For this purpose, the heat exchanger 1 has an insulating element 15, which in the example shown is designed as a cooling channel 15. In the context of the invention, the term “cooling channel” is therefore to be understood as synonymous with “insulating element”. The insulating element 15 preferably consists, at least in sections, of a plastic and separates the region in which the first fluid medium 22 is arranged from that in which the second fluid medium 4 is guided.

The heat exchanger 1 comprises a first passage opening 5 in the insulating element 15, into which a first cooling connection element 6 or first heat transfer element 6 is inserted. The first cooling connection element 6 is in thermal connection on the one hand with the second fluid medium 4 of the cooling circuit 3 and on the other hand with the first ancillary component 2, in order to cool the first ancillary component 2.

Preferably, the heat exchanger 1 has sectionally stiffenings 14 in the insulating element 15, which ensure that the heat transfer element 6 is securely held. Such a stiffening 14 can also be designed as a housing, which can be form-fittingly connected to the heat source 2, 100, for example, clipped on. In such an embodiment, the design of the heat exchanger 1 is set sectionally, in particular the design of the cooling circuit 3, in order to be able to bring this section into the direct vicinity of the heat source 2, 100 in a form fit and/or in a particularly space-saving manner.

The first cooling connection element 6 is designed as a screw element 12 with a screw head 16 and a threaded part 18. Furthermore, the passage opening 5 has a thread 13, wherein the thread 13 and the threaded part 18 are formed to match each other, so that the threaded part 18 can be screwed into the thread 13. In particular, a form fit of the threaded part 18 in the passage opening 5 is provided.

The cooling connection element 6 has a coolant-side end 19 and an ancillary component-side or heat source-side end 20, wherein the coolant-side end 19 is in connection with the cooling medium 4 and the ancillary component-side end 20 is in connection with the ancillary component 2 or heat source 2.

The coolant-side end 19 has a structure 7 which is provided and designed to increase a contact area between the cooling connection element 6 and the cooling medium 4. This enables improved thermal transport from the ancillary component 2 to the cooling circuit 3 and correspondingly improved cooling.

According to the embodiment shown, the structure 7 is designed as a pin heat sink, a so-called pin fin structure 8, with several pins 21 projecting into the cooling medium 4.

At the ancillary component-side end 20, the cooling connection element 6 is in thermal connection with the ancillary component 2, particularly preferably by means of a third heat transfer element, which in the example shown is formed as a first heat conducting layer 11. The third heat transfer element is arranged between the ancillary component 2 and the cooling connection element 6. Preferably, unevenness between the ancillary component 2 and the cooling connection element 6 can be compensated for by means of a heat conducting layer 11, so that the largest possible contact area is formed in order to optimize the thermal connection.

A sealing element 9 is preferably provided to seal the cooling circuit 3 and in particular to prevent cooling medium from escaping through the passage opening 5 to the outside or to prevent the first fluid medium 22 from entering the cooling circuit 3. According to the embodiment shown, the sealing element 9 is formed as an O-ring 10, which is arranged between the housing 14 and the screw head 16. Particularly preferably, the screw head 16 has a recess 17 for this purpose, in which the O-ring 10 is arranged in such a way that the O-ring 10 seals the passage opening 5 with respect to the outside. The recess 17 is preferably complementary to the O-ring 10, or has retaining means, so that the O-ring 10 is secured against falling out easily.

According to the invention, the same cooling circuit 3 can also be used to cool a power module 100 of the power electronics 1000, which is only shown schematically, so that several heat sources 2, 100, preferably the entire power electronics 1000, can be cooled by the heat exchanger 1. Thus, only a single cooling circuit 3 is provided for cooling the power electronics 1000 with the power module 100 and the ancillary components 2.

The power module 100 is shown purely schematically. It could be thermally connected to the cooling circuit 3 in the same way as shown for the ancillary component 2. Alternatively, it could also be cooled directly by means of the cooling circuit 3, for example by flowing around with cooling medium 4, or indirectly by means of any cooling structures arranged on the power module 100 and flushed with cooling medium 4.

The various embodiments with all their features can be combined and interchanged as desired.

All features disclosed in the application documents are claimed to be essential to the invention insofar as they are new, individually or in combination, compared to the prior art.

### LIST OF REFERENCE SIGNS

1 heat exchanger
2 (second) heat source, ancillary component
3 cooling circuit
4 second fluid medium, cooling medium
5 (first or second) passage opening, Disconnection, opening
6 (first or second) heat transfer element, first cooling connection element
7 structure
8 pin heat sink, pin fin structure
9 sealing element
10 O-ring
11 third heat transfer element, first heat conducting layer
12 screw element
13 thread
14 stiffening, housing
15 insulating element, cooling channel
16 screw head
17 recess
18 threaded part
19 coolant-side end
20 ancillary component-side end
21 pin
22 first fluid medium
100 (first) heat source, power module
1000 power electronics

While the preferred embodiment of the invention has been illustrated and described, as noted above, many changes can be made without departing from the spirit and scope of the invention. Accordingly, the scope of the invention is not limited by the disclosure of the preferred embodiment. Instead, the invention should be determined entirely by reference to the claims that follow.

1. A heat exchanger comprising:
an insulating element, wherein the insulating element separates a first fluid medium, which is in contact with a heat source, from a second fluid medium, which differs in at least one property from the first fluid medium and which is in fluid connection and/or contact with a heat sink or is itself a heat sink, and
a first heat transfer element which comprises a higher thermal conductivity than the insulating element,
wherein
the insulating element comprises a first passage opening in which the first heat transfer element is arranged, and
the first heat transfer element is thermally connected both to the first fluid medium and/or the heat source, and to the second fluid medium and together with a sealing element fluidically seals the passage opening.

2. The heat exchanger according to claim 1, wherein a material of the first heat transfer element is selected from a group comprising copper, gold, silver, brass, tungsten, iron, aluminum, magnesium, silicon and alloys with at least one of these metals.

3. The heat exchanger according to claim 1, wherein the first heat transfer element is in thermal connection with the second fluid medium by means of a pin heat sink.

4. The heat exchanger according to any claim 1, wherein the sealing element is an O-ring.

5. The heat exchanger according to claim 1, wherein
the first heat transfer element is designed as a screw element and is screwed into the first passage opening, and
the screw element preferably comprises a screw head which has a geometry selected from a group comprising external hexagon, external square, internal hexagon, hexalobular internal, slot and cross slot, and which is preferably suitable for form-fitting with a tool.

6. The heat exchanger according to claim 1, wherein
the first heat transfer element is thermally connected to the first heat source, which is preferably a power module, by means of the first fluid medium or a further third heat transfer element, and
the third heat transfer element is preferably selected from a group comprising a heat conductive paste, a gap pad, an adhesive and metal.

7. The heat exchanger according to claim 1, wherein
at least one second heat transfer element is provided, which is arranged in a second passage opening of the insulating element-, and
the second heat transfer element is thermally connected both to the first fluid medium and/or a further heat source, and to the second fluid medium and is fluidically sealed with respect to the insulating element by means of a sealing element.

8. The heat exchanger according to claim 7, wherein
the second heat transfer element is thermally connected to the further heat source, which is preferably an ancillary component, by means of the first fluid medium or a further third heat transfer element, and
the third heat transfer element is preferably selected from a group comprising a heat conductive paste, a gap pad, an adhesive and metal.

9. The heat exchanger according to claim 1, wherein the second fluid medium is part of a cooling circuit.

10. The heat exchanger according to claim 1, wherein the insulating element comprises a plastic, preferably consists at least partially of a plastic and further preferably consists predominantly of a plastic and in particular is preferably made of a plastic.

11. The heat exchanger according to claim 1, wherein the at least one ancillary component is at least one selected from the group comprising a DC link, a busbar, a switch element.
